(19) United States
(12) Patent Application Publication
(10) Pub. No.: US 2007/0268089 A1
(43) Pub. Date: Nov. 22, 2007

(54) Plasma Immersion Ion Implantation Using Conductive Mesh

(76) Inventors: David Robert McKenzie, Artarmon (AU); Rebecca Powles, Chippendale (AU)

Correspondence Address: MCCARTER & ENGLISH , LLP STAMFORD OFFICE, FINANCIAL CENTRE , SUITE 304A, 695 EAST MAIN STREET, STAMFORD, CT, 06901-2138, US

(21) Appl. No.: 10/577,604

(22) PCT Filed: Oct. 28, 2004
(86) PCT No.: PCT/AU04/01489

§ 371 Date: Mar. 27, 2007

(30) Foreign Application Priority Data
Oct. 31, 2003 (AU) 2003906051

(51) Int. Cl. H01J 37/32; C23C 14/20

(52) U.S. Cl. 333/99 PL; 427/523

(57) ABSTRACT

A plasma process (5) for modifying at least a region of a surface of a component (1); wherein the component (1) is bombarded by ions from a gas plasma environment (4); and the ions are drawn towards the component (1) by a voltage source applied to a first mesh (3). The first mesh (3) is a stationary non-conformal mesh (3), and the component (1) does not contact the first mesh (3). The component (1) is moved (2) in the vicinity of the first mesh (3) to evenly expose it to ion bombardment (4).

### FIELD OF THE INVENTION

The present invention relates to a plasma processor and a method for modifying the surface of components by plasma ion implantation.

### BACKGROUND

Plasma Immersion Ion Implantation (‘PIII’) is a well known method for modifying the surface of electrically conductive components. In the past, PIII methods were comprised of mounting an electrically conductive component on a stage or support immersed in a plasma environment. High voltage pulses of the opposite charge to the plasma ion species is applied to the outer surface of the component by attachment to the support. This application of voltage attracts ions from the plasma to implant into the outer surface of the component. This method has several disadvantages which include: the method is not capable of substantially uniformly modifying the surface of a component with a complex shape; and the method is not suitable for modifying the surface of non-electrically conductive components.

Previously, PIII of electrically non-conductive component may be achieved by mounting the component on a conductive support and applying a high voltage to the support. However, the non-conducting component may accumulate a charge which may repel incoming ions. This effect leads to a sharp decline in the amount of ions implanted within the surface and reduces the efficiency of the process.

In the past, this effect has been overcome by depositing a thin layer of conductive material in the outer surface of the non-conductive component and then performing the PIII treatment. This treatment may lead to additional processing steps and may contaminate the component.

As disclosed in U.S. Pat. No. 5,945,012—Chan, it is also previously known that conductive and non-conductive components may be tumbled within a rotating barrel. The rotating barrel comprises a conductive mesh that is electrically connected to a high voltage AC power source and attracts ions from the plasma towards the components. The components can also be of complex shapes as the tumbling of the components allows all facets of the components to be exposed. One disadvantage of this mechanism is that the components are allowed to contact the biased conductive mesh and this may result in increasing the temperature exposure of the components or scorch the surface of the components.

It is an object of the present invention to address or ameliorate one or more of the abovementioned disadvantages.

### SUMMARY OF INVENTION

In accordance with a first aspect the present invention consists in a plasma processor for modifying at least a region of a surface of a component; wherein said component is bombarded by ions from a gas plasma environment; said ions are drawn towards said component by a voltage source applied to a first mesh, wherein said first mesh is a stationary non-conformal conductive mesh; characterised in that the component does not contact the first mesh and the component is moved in the vicinity of said first mesh to evenly expose it to ion bombardment.

Preferably said first mesh substantially encapsulates said component.

Preferably said component is mounted on an oscillating and/or rotating support.

Preferably said component is encapsulated by a movable second mesh that is a non-conformal non-conductive mesh encapsulated within the first mesh.

Preferably said voltage source provides a pulsed voltage.

Preferably said component is non-conducting.

Preferably said component is a polymeric component.

Preferably said component is part of a blood pump.

In accordance with a second aspect the present invention consists in a method for modifying a surfaces of a component; wherein said component is bombarded by ions from a gas plasma environment; said ions are drawn towards said component by a voltage source applied to a first mesh, wherein said first mesh is a stationary non-conformal conductive mesh; characterised in that the component does not contact the first mesh and the component is moved in the vicinity of said first mesh to evenly expose it to ion bombardment.

Preferably said component is mounted on an oscillating and/or rotating support.

Preferably said component is encapsulated by a movable second mesh that is a non-conformal non-conductive mesh encapsulated within the first mesh.

Preferably said voltage source provides a pulsed voltage.

Preferably said component does not contact said first mesh.

Preferably said component is non-conducting.

Preferably said component is a polymeric component.

Preferably said component is part of a blood pump.

### BRIEF DESCRIPTION OF DRAWINGS

Embodiments of the invention will now be described with reference to the drawings in which:

FIG. 1 is a schematic view of a first embodiment of the present invention;

FIG. 2 is a schematic view of a second embodiment of the present invention;

FIG. 3 is a graphical representation of a voltage applied in an embodiment in accordance with a method;

FIG. 4 is a second graphical representation of a voltage applied in an embodiment in accordance with a method; and

FIG. 5 is a perspective view of a portion of a further embodiment of the present invention.

### BEST MODE OF CARRYING OUT INVENTION

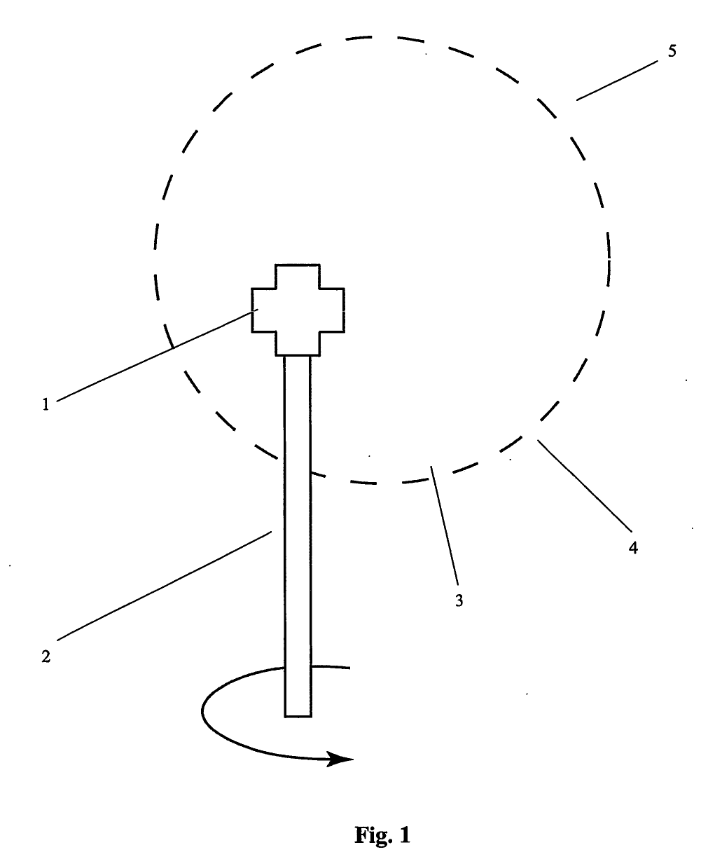

FIG. 1 depicts a first embodiment of the present invention. This embodiment may include a method and/or a device to implant ions into a component 1, wherein said component is treated through plasma immersion ion implantation and or plasma deposition to modify and/or coat the outer surface of the component 1. The implantation of these ions may extend up to an approximate depth of 1 micrometer into said outer surface of the component 1.

Preferably, the component 1 is immersed in gas plasma environment 4, which may be created by an RF antenna (not shown) placed in a background of the desired gas. High voltage pulses will be applied to an electrode in proximity to the component using a power supply. Alternatively, the power supply may be used in the absence of the RF antenna to create the plasma and induce the implantation of ions. Any plasma source compatible with the gases and high-voltage pulsing may be used including RF, glow discharge and ECR. The desired background gases may include one or more of the following: hydrogen, argon, helium, nitrogen, oxygen, acetylene, ethane, methane, other hydrocarbon gas and/or mixtures thereof. A carbon plasma background generated by a cathodic arc may also be used. The power supply may utilise either AC or DC voltages.

The component 1 is preferably surrounded by a first mesh 3. The first mesh 3 may be a non-conformal mesh (meaning it does not conform specifically to the shape or configuration of the component 1); including a plurality of holes or pores and may constructed of electrically conductive material. When in use, the plasma processor 5 induces ions to leave the plasma environment 4 and move towards the first mesh 3, which acts as a target for the ions. Preferably, the first mesh 3 is electrically conductive and biased with a high voltage which is of the opposed sign to the charge state of the ions occurring in the plasma environment 4.

There may also be a region of relatively depleted ions and/or electrons, termed a plasma sheath, in close proximity to the first mesh 3. In the plasma sheath, an electric field is present and this field accelerates ions entering from the plasma environment 4 so that ions cross the plasma sheath and gain energy from the electric field. Preferably, at least a portion of these ions pass through the plurality of holes or pores in the first mesh 3. These ions travel at high velocity and impact into the outer surface of the component 1.

Preferably, the component 1 may be rotated and/or oscillated within the first mesh 3 so as to expose all outer surfaces of the component 1. This rotation and/or oscillation may be achieved by the use of a stage or support 2 to which the component 1 is preferably attached. As component 1 is rotated, so as to allow the position of the component 1 to change position in respect of the holes or pores of the first mesh 3. The effect of rotating and/or oscillating the component 1 may be that the resulting ion implantation may be relatively evenly distributed. The support 2 may preferably be insulated from the high voltage feed (not shown) which is connected to the first mesh 3.

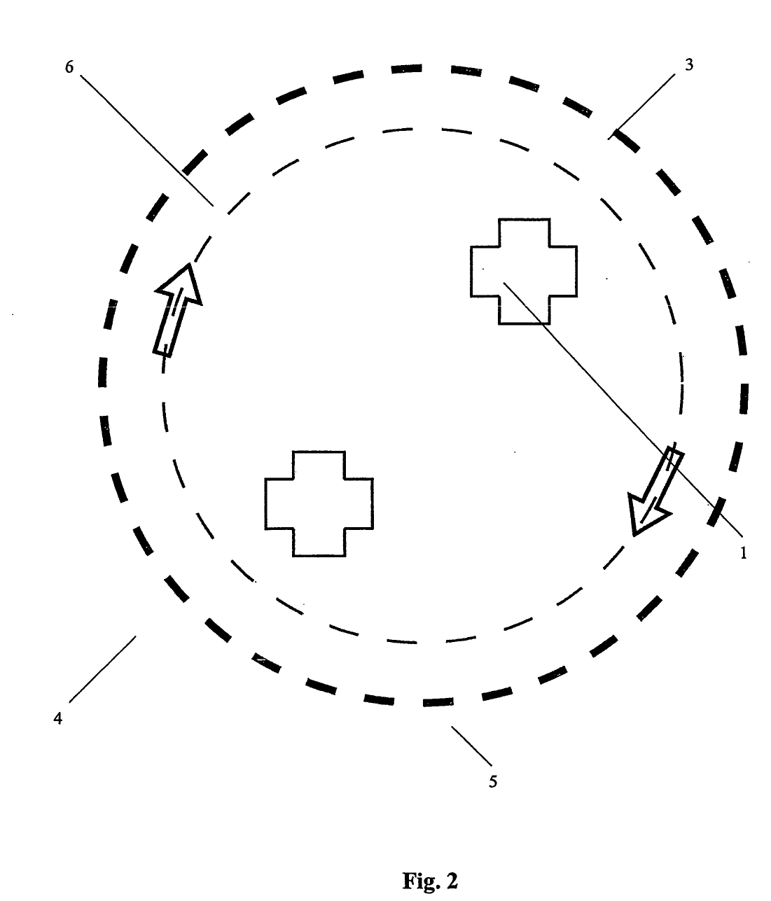

In a further embodiment, depicted in FIG. 2, a second mesh 6 surrounds the component 1 in preferably a non-conformal manner. The second mesh 6 may be oscillated and/or rotated so that that the work piece tumbles within the second mesh 6 and thereby facilitating a relatively even coverage of ions entering the surface of the component 1. The second mesh 6 is positioned between the component 1 and the first mesh 3.

Preferably, the second mesh 6 is electrically non-conductive and allows the component 1 to move and be processed without contacting the first mesh 3. The prevention of the component 1 from contacting the first mesh 3 may prevent the component 1 from being overheated or adversely affected by the high voltage applied to the first mesh 3.

A relatively high voltage is applied to the first mesh 6 by means of a high voltage feed (not shown) and this feed may be in turn connected to a power supply (not shown).

The average energy of ions reaching the surface of the component 1 may be adjusted by varying the voltage applied to the first mesh 3 and/or the distance between the first mesh 3 and the second mesh 6. Additionally, the choice of background gas may also be useful to adjust the average energy of ions reaching the surface of the component 1.

The first mesh 3 is preferably able to carry a pulsed voltage or potential with respect to the plasma or chamber generated by the power supply (not shown) and supplied to the mesh by a feed. Preferably, neither the first mesh 3, the feed nor the power supply are able to rotate or oscillate. The voltage or potential applied to the first mesh 3 is relatively high and may be approximately in the range of 2 kV to 20 kV, preferably 10 kV.

Please note that as the ion implantation of the component 1 progresses, the implantation of ions generates a charge on the surface of the component 1. This charge may potentially block or impede further implantation of ions. Therefore the charge on the outer surface of the component 1 should be periodically neutralized, with a pulsed voltage being applied to the first mesh 3 instead of a constant voltage. The net effect of the pulsed voltage or potential on the first mesh 3 is such that the surface charge on the component 1 is periodically neutralized by the outside environment and this in turn allows continuing implantation or plasma-assisted deposition to occur.

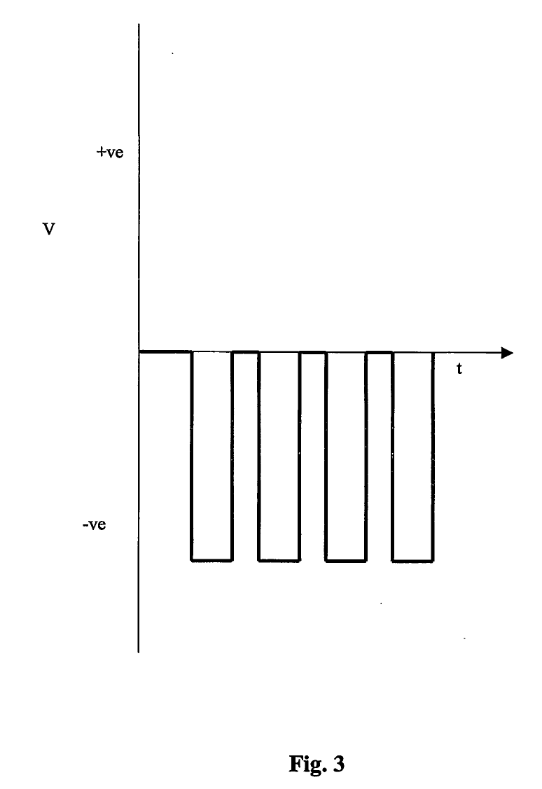

FIG. 3 shows a graphical representation of a preferred method of the application of a pulsed voltage to the first mesh 3. This method may be useful for improving the rate of neutralization of the positive charge arising from the ions implanted into the component 1. It is particularly useful when the component 1 is electrically non-conductive. In FIG. 3, a negative charge is periodically applied to the first mesh 3 and this may allow the component 1 to be periodically neutralised

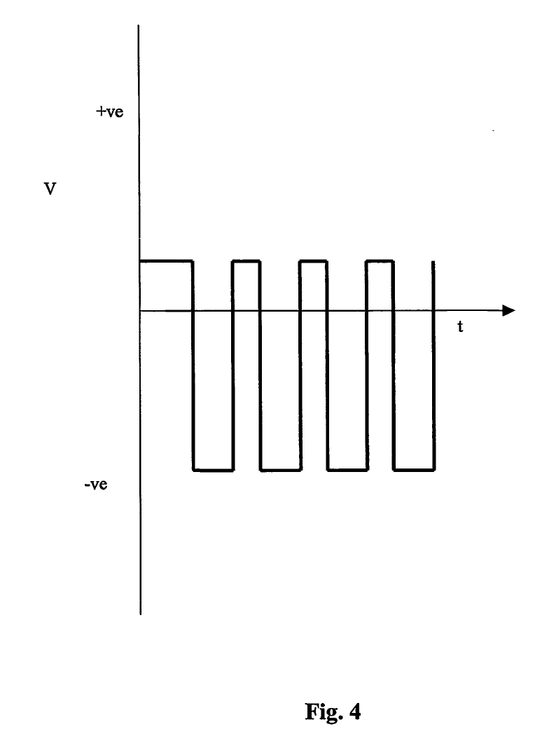

A further embodiment of a similar method is represented in FIG. 4. In this embodiment, positive and negative voltages are applied to the first mesh 3. These negative and positive pulses occur alternately. The negative pulses attract the ions to be implanted and the positive pulses attract electrons to neutralize the positive charge that builds up on the surface of the component 1. The net effect is to periodically neutralise the charge on component 1. The process shown in this embodiment is generally termed a ‘Bipolar’ process.

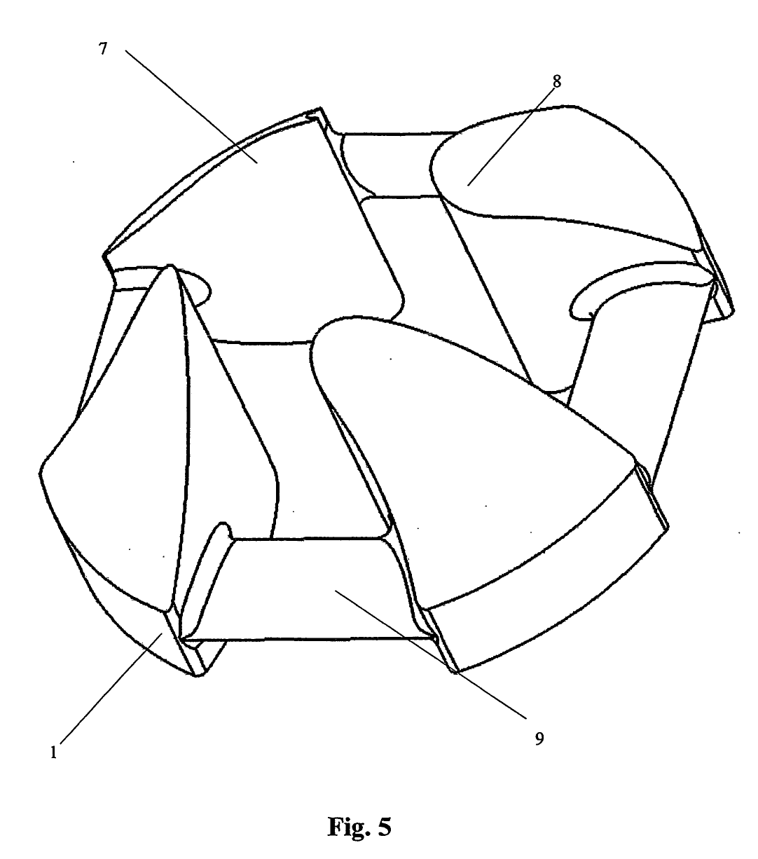

FIG. 5 shows a preferred component 1 to be modified by one of the preferred embodiments of the present invention. The component 1 shown is preferably a medical device and specifically may be an impeller 8 for an implantable blood pump. The impeller 8 includes four blades 7 connected by struts 9 in a generally square configuration. The component 1 may be preferably constructed of an electrically non-conductive material, including but not limited to polymers.

In a further embodiment, a cylindrical vacuum chamber pumped by a rotary/diffusion pump to a base pressure of about 1.0×10⁻⁵ Torr. H₂ gas is introduced via a flow controller to bring cylindrical vacuum chamber pressure to around 15 mTorr, this in turn may form the gas plasma environment discussed in previous embodiments.

In the gas plasma environment, a first mesh is a conductive mesh in a spherical stainless steel mesh configuration with radius of approximately 10 cm. The first mesh has a small opening on one side to allow a non-conducting PTFE rod to pass through. The PTFE rod is attached at the chamber wall to a vacuum rotary feedthrough so that it can rotate freely about its axis and the PTFE rod serves a similar function as to the rotating or oscillating support of previous embodiments. The component, in this embodiment is a small block of PEEK polymer, which is preferably attached to the end of the PTFE rod, which is inside the first mesh. This configuration of PTFE rod and mounted component places the component approximately in the centre of the first mesh where it can be rotated during implantation. The component is preferably rotated by the rotation of PTFE rod during treatment and thereby allows a relative even ion implantation treatment. The first mesh is preferably attached to an ANSTO™ pulser, which is operated so as to deliver −15 kV pulses of 15 μs duration at a frequency of 1000 Hz. When operating, this embodiment generates a glow discharge around the first mesh, which may be visually observed and may also monitored by the characteristic shape of the current and voltage pulses from the pulser shown by an oscilloscope. This treatment is preferably applied for a period of approximately 2 minutes.

The component, after treatment, may be strongly darkened in colour. The relatively even darkened colour over the surface of the component may demonstrate the generally even coverage of this treatment. Additionally, this treatment shows no ‘shadow effect’ due to the mesh which typically occurs with use of the prior art treatments and also the component is generally not burnt or melted as there is no direct contact between the component and the first mesh, which is heated by ion impact during treatment.

Various additional modifications are possible within the scope of the foregoing specification and accompanying drawings without departing from the scope of the invention.

The claims defining the invention are as follows:

1. A plasma processor for modifying at least a region of a surface of a component;
wherein said component is bombarded by ions from a gas plasma environment; said ions are drawn towards said component by a voltage source applied to a first mesh, wherein said first mesh is a stationary non-conformal conductive mesh; characterised in that the component does not contact the first mesh and the component is moved in the vicinity of said first mesh to evenly expose it to ion bombardment.

2. The plasma processor as claimed in claim 1, wherein said first mesh substantially encapsulates said component.

3. The plasma processor as claimed in claim 2, wherein said component is mounted on an oscillating and/or rotating support.

4. The plasma processor as claimed in claim 2, wherein said component is encapsulated by a movable second mesh that is a non-conformal non-conductive mesh encapsulated within the first mesh.

5. The plasma processor as claimed in claim 1, wherein said voltage source provides a pulsed voltage.

6. The plasma processor as claimed in claim 1, wherein said component is non-conducting.

7. The plasma processor as claimed in claim 1, wherein said component is a polymeric component.

8. The plasma processor as claimed in claim 7, wherein said component is part of a blood pump.

9. A method for modifying a surfaces of a component; wherein said component is bombarded by ions from a gas plasma environment; said ions are drawn towards said component by a voltage source applied to a first mesh, wherein said first mesh is a stationary non-conformal conductive mesh; characterised in that the component does not contact the first mesh and the component is moved in the vicinity of said first mesh to evenly expose it to ion bombardment.

10. The method as claimed in claim 9, wherein said component is mounted on an oscillating and/or rotating support.

11. The method as claimed in claim 9, wherein said component is encapsulated by a movable second mesh that is a non-conformal non-conductive mesh encapsulated within the first mesh.

12. The method as claimed in claim 9, wherein said voltage source provides a pulsed voltage.

13. The method as claimed in claim 9, wherein said component does not contact said first mesh.

14. The method as claimed in claim 9, wherein said component is non-conducting.

15. The method as claimed in claim 9, wherein said component is a polymeric component.

16. The method as claimed in claim 9, wherein said component is part of a blood pump.
